(19) United States
(12) Patent Application Publication
(10) Pub. No.: US 2026/0319359 A1
(43) Pub. Date: Oct. 15, 2026

(54) MULTILAYER MOLECULAR FILM PHOTORESIST HAVING MOLECULAR LINE STRUCTURE COMPRISING ORGANIC MONOMERS HAVING CROSS-LINKING FUNCTIONAL GROUPS, AND PREPARATION METHOD THEREFOR

(71) Applicant: HUNETPLUS CO. LTD, Cheonan-si., (KP)

(72) Inventors: Myung Mo SUNG, Seoul (KR); Yeong Eun BAK, Seoul (KR); Hyeon Seok JI, Seoul (KR); Jae Hyuk LEE, Seoul (KR); Jinho AHN, Seoul (KR)

(73) Assignee: HUNETPLUS CO., LTD., Cheonan- si, Chungoheongnam-do (KR)

(21) Appl. No.: 19/154,890

(22) PCT Filed: Feb. 8, 2024
(86) PCT No.: PCT/KR2024/001924

§ 371 Date: Aug. 8, 2025

(30) Foreign Application Priority Data
Feb. 10, 2023 (KR) 10-2023-0017921
Feb. 8, 2024 (KR) 10-2024-0019407

(51) Int. Cl. G03F 7/004; G03F 7/095

(52) U.S. Cl. CPC G03F 7/0042; G03F 7/095

(57) ABSTRACT

A multilayer molecular film photoresist is provided. The multilayer molecular film photoresist comprises a plurality of molecular lines extending upward from a substrate and arranged laterally. Each molecular line comprises linearly connected monomers represented by the following Chemical Formula 1:

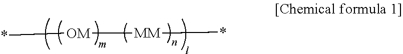

In Chemical formula 1, one of the *s is a bond to a functional group in a lower monomer, and the other is a bond to a functional group in an upper monomer; OM is an organic monomer; MM is a main inorganic monomer comprising a main metal atom; m is 1 to 2, n is 1 to 2, and l is 1 to 1000. A side inorganic monomer including a metal atom is positioned between the molecular lines and bonded to a side of the organic monomer (OM) in one of the molecular lines. A crosslinking functional group is bonded to a side of the organic monomer (OM) in another of the molecular lines.

### TECHNICAL FIELD

The present invention relates to a photoresist, and more particularly, to a photoresist for EUV.

### BACKGROUND ART

Research has been continuously conducted on photoresists, and in particular, the method of producing a liquid photoresist and then depositing it on a substrate by spin coating has been most actively studied. As such traditional photoresist, chemically amplified resist (CAR) containing polymer resin, PAG (Photo-Acid Generator), and base (quencher) is mainly used.

Recently, the semiconductor industry is introducing extreme ultraviolet (EUV) photolithography, which uses an EUV light source capable of forming ultra-fine patterns of 10 nm or less.

However, EUV has a low photon density of 1/14 compared to deep UV (DUV) of 193 nm, so it can cause stochastic failure, specifically photon shot noise. For example, in the case of the CAR, shot noise may occur due to low probability of PAG participating in the reaction due to low photon density. In addition, CAR is known to have the disadvantage of exhibiting relatively large line edge roughness because the size of the polymer resin particles is larger than 4 nm.

### DISCLOSURE

### Technical Problem

Therefore, the problem to be solved by the present invention is to provide a photoresist with excellent photon absorption and low line edge roughness, and a method for manufacturing the same.

The technical problems of the present invention are not limited to the technical problems mentioned above, and other technical problems not mentioned will be clearly understood by those skilled in the art from the following description.

### Technical Solution

According to one embodiment of the present invention, a multilayer molecular film photoresist is provided. The multilayer molecular film photoresist comprises a plurality of molecular lines extending upward from a substrate and arranged laterally. Each molecular line comprises linearly connected monomers represented by the following Chemical Formula 1:

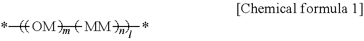

in the Chemical formula 1, one of the *s is a bond to a functional group in a lower monomer, and the other is a bond to a functional group in an upper monomer, OM is an organic monomer, MM is a main inorganic monomer comprising a metal atom, m is 1 to 2, n is 1 to 2, and l is 1 to 1000.

A side inorganic monomer comprising a metal atom is positioned between the molecular lines and bonded to a side of the organic monomer (OM) in one of the molecular lines. A crosslinking functional group is bonded to a side of the organic monomer (OM) in another of the molecular lines.

Van der Waals interactions may exist between the organic monomers within the laterally adjacent molecular lines.

The main inorganic monomer may be represented by the following Chemical Formula 2:

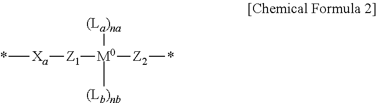

in the Chemical Formula 2, one of the *s may be a bond with a functional group in a lower monomer, and the other may be a bond with a functional group in an upper monomer. Xₐ may be O, S, Se, NR (R is H or CH₃), or PR (R is H or CH₃). M⁰ is the metal atom and M⁰ may be Sn, Sb, Te, Bi, Zr, Al, Hf, Zn, In, Al, Ti, Cu, W, or Si. Z₁ and Z₂ may be, regardless of each other, a direct bond, a substituted or unsubstituted linear or branched alkylene group having 1 to 20 carbon atoms, a substituted or unsubstituted linear or branched alkylene oxide having 1 to 20 carbon atoms, a substituted or unsubstituted linear or branched alkyleneamino having 1 to 20 carbon atoms, a substituted or unsubstituted linear or branched alkylenesilylamino having 1 to 20 carbon atoms, a substituted or unsubstituted linear or branched alkylenethio having 1 to 20 carbon atoms, a substituted or an unsubstituted linear or branched alkyleneseleno having 1 to 20 carbon atoms, or a substituted or unsubstituted linear or branched alkylenephosphino having 1 to 20 carbon atoms. Lₐ and L_{b}, regardless of each other, may be a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, a C1 to C5 alkylphosphino group, acetate, or aryloxy. The sum of na and nb may be an integer from 0 to 4. In an example, both na and nb may be 0.

The side inorganic monomer may be represented by the following Chemical Formula 3:

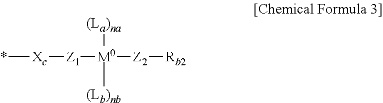

in the Chemical Formula 3, * may be a bond with the organic monomer. X_{c} may be O, S, Se, NR (R is H or CH₃), or PR (R is H or CH₃). M⁰ is the metal atom and M⁰ may be Sn, Sb, Te, Bi, Zr, Al, Hf, Zn, In, Al, Ti, Cu, W, or Si. Z₁ and Z₂ may be, regardless of each other, a direct bond, a substituted or unsubstituted linear or branched alkylene group having 1 to 20 carbon atoms, a substituted or unsubstituted linear or branched alkylene oxide having 1 to 20 carbon atoms, a substituted or unsubstituted linear or branched alkyleneamino having 1 to 20 carbon atoms, a substituted or unsubstituted linear or branched alkylenesilylamino having 1 to 20 carbon atoms, a substituted or unsubstituted linear or branched alkylenethio having 1 to 20 carbon atoms, a substituted or an unsubstituted linear or branched alkyleneseleno having 1 to 20 carbon atoms, or a substituted or unsubstituted linear or branched alkylenephosphino having 1 to 20 carbon atoms. Lₐ and L_{b}, regardless of each other, may be a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, a C1 to C5 alkylphosphino group, acetate, or aryloxy. The sum of na and nb may be an integer from 0 to 4. R_{b2} may be a halogen group (e.g., Cl, Br, or I), a C1 to C5 alkyl group, a C1 to C5 alkylsilylamino group, a C1 to C5 alkoxy, a C1 to C5 alkylthio group, a C1 to C5 alkylseleno group, a C1 to C5 alkylamino group, or a C1 to C5 alkylphosphino group. In an example, both na and nb may be 0.

The crosslinking functional group may be *—Z₅X_{c}Rₐ₃, wherein * may be a bond with the organic monomer. Z₅ may be a direct bond or a substituted or unsubstituted, linear or branched alkylene group having C1 to C5, specifically C1 to C3. X_{c} may be O, S, Se, NR (R is H or CH₃), or PR (R is H or CH₃). Rₐ₃ may be hydrogen or a C1 to C2 alkyl group.

The organic monomer may be represented by the following Chemical Formula 4:

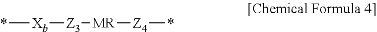

in the Chemical Formula 4, one of the *s may be a bond with a functional group in a lower monomer, and the other may be a bond with a functional group in an upper monomer. X_{b} may be O, S, Se, NR (R is H or CH₃), or PR (R is H or CH₃). Z₃ and Z₄ may be, regardless of each other, direct bonds or linear or branched alkylene groups having C1 to C5. MR may be a body having a linear chain having 2 to 7 carbons or a non-aromatic or aromatic ring having 3 to 18 carbons. The side inorganic monomer or the crosslinking functional group may be bonded to the body (MR). In an example, the MR may be a linear alkylene group having C2 to C6.

According to another embodiment of the present invention, a multilayer molecular film photoresist is provided. The multilayer molecular film photoresist comprises a plurality of molecular lines extending upwardly from a substrate and arranged laterally. Each molecular line comprises linearly connected monomers, wherein the monomers comprise a plurality of main inorganic monomers including metal atoms and organic monomers connected between at least some of the main inorganic monomers. Side inorganic monomers comprising metal atoms are positioned between the molecular lines and bonded to sides of the organic monomers.

The main inorganic monomers and organic monomers located within the molecular lines may be connected by one bond selected from the group consisting of —O—, —S—, —Se—, —NR— (R is H or CH₃) and —PR— (R is H or CH₃) contained in any one of these monomers. The organic monomers and the side inorganic monomers may be connected by one bond selected from the group consisting of —O—, —S—, —Se—, —NR— (R is H or CH₃) and —PR— (R is H or CH₃) contained in any one of these monomers.

The metal atom contained in the main inorganic monomer or the side inorganic monomer may be Sn, Sb, Te, Bi, Zr, Al, Hf, Zn, In, Ti, Cu, W, or Si. Van der Waals interactions may exist between the organic monomers within the laterally adjacent molecular lines among the molecular lines. Each of the molecular lines may be formed by alternating stacking of the main inorganic monomers and the organic monomers. The multilayer molecular film photoresist may be a photoresist for EUV.

According to another embodiment of the present invention, a method for manufacturing a photoresist pattern is provided. A multilayer molecular film photoresist is provided. The multilayer molecular film photoresist comprises a plurality of molecular lines extending upward from a substrate and arranged laterally. Each molecular line comprises linearly connected monomers represented by the following Chemical Formula 1:

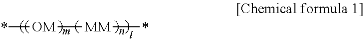

in Chemical formula 1, one of the *s is a bond to a functional group in a lower monomer, and the other is a bond to a functional group in an upper monomer. OM is an organic monomer. MM is a main inorganic monomer comprising a metal atom. m is 1 to 2, n is 1 to 2, and l is 1 to 1000.

A side inorganic monomer comprising a metal atom is positioned between the molecular lines and bonded to a side of the organic monomer (OM) in one of the molecular lines. A crosslinking functional group bonded to a side of the organic monomer (OM) in another of the molecular lines.

A portion of the multilayer molecular film photoresist is irradiated with Ebeam or EUV radiation to crosslink the side inorganic single molecules with the crosslinkable functional group. The portion of the multilayer molecular film photoresist not exposed to the radiation is developed and removed.

According to another embodiment of the present invention, a method for manufacturing a photoresist pattern is provided. The method for manufacturing a photoresist pattern comprises loading a substrate into a chamber having a gas inlet and a gas outlet. An organic precursor sub-cycle is performed. The organic precursor sub-cycle includes supplying an organic precursor of the following Chemical Formula 5 into the chamber with the gas outlet closed, reacting the organic precursor on the substrate, and then purging any remaining reaction gas within the chamber. An inorganic precursor sub-cycle is performed. The inorganic precursor sub-cycle includes supplying an inorganic precursor of the following Chemical Formula 6 into the chamber with the gas outlet closed, reacting the inorganic precursor on the organic precursor, and then purging any remaining reaction gas within the chamber. Multiple unit cycles including the organic precursor sub-cycle and the inorganic precursor sub-cycle are performed to form a multilayer molecular film photoresist. A portion of the multilayer molecular film photoresist is irradiated with Ebeam or EUV radiation. An area of the multilayer molecular film photoresist not exposed to the radiation is developed and removed.

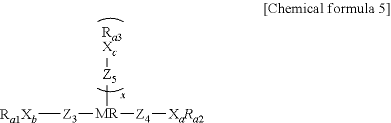

in the Chemical Formula 5, Rₐ₁, Rₐ₂, and Rₐ₃ are hydrogen or C1 to C2 alkyl groups regardless of each other. Xₐ, X_{b}, and X_{c} are O, S, Se, NR (R is H or CH₃) or PR (R is H or CH₃) regardless of each other. Z₃, Z₄, and Z₅ are direct bonds or substituted or unsubstituted and linear or branched alkylene groups of C1 to C3 regardless of each other. MR is a body having a linear chain having 2 to 7 carbons or a non-aromatic or aromatic ring having 3 to 18 carbons. x is 1 or 2.

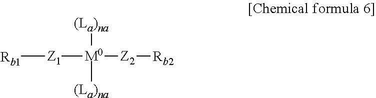

in the Chemical Formula 6, R_{b1} and R_{b2}, regardless of each other, are a halogen group, a C1 to C5 alkyl group, a C1 to C5 alkylsilylamino group, a C1 to C5 alkoxy, a C1 to C5 alkylthio group, a C1 to C5 alkylseleno group, a C1 to C5 alkylamino group, or a C1 to C5 alkylphosphino group. M⁰ is Sn, Sb, Te, Bi, Zr, Al, Hf, Zn, In, Al, Ti, Cu, W, or Si. Z₁ and Z₂ are, regardless of each other, a direct bond, a substituted or unsubstituted linear or branched alkylene group having 1 to 20 carbon atoms, a substituted or unsubstituted linear or branched alkylene oxide having 1 to 20 carbon atoms, a substituted or unsubstituted linear or branched alkyleneamino having 1 to 20 carbon atoms, a substituted or unsubstituted linear or branched alkylenesilylamino having 1 to 20 carbon atoms, a substituted or unsubstituted linear or branched alkylenethio having 1 to 20 carbon atoms, a substituted or an unsubstituted linear or branched alkyleneseleno having 1 to 20 carbon atoms, or a substituted or unsubstituted linear or branched alkylenephosphino having 1 to 20 carbon atoms. Lₐ and L_{b}, regardless of each other, are a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, a C1 to C5 alkylphosphino group, acetate, or aryloxy. The sum of na and nb is an integer from 0 to 4.

### Advantageous Effects

When a multilayer molecular film photoresist according to one embodiment of the present invention is exposed and developed, molecular lines, rather than particles, can be separated. Therefore, the line edge roughness (LER), which represents the side roughness of the pattern, can be reduced, and the resolution can also be improved.

Furthermore, the multilayer molecular film photoresist, for example, comprises metal atoms with extremely high absorption coefficients for EUV, enabling it to exhibit high photosensitivity with low stochastic failure, even under low photon density EUV conditions.

In addition, the multilayer molecular film photoresist comprises a side inorganic monomer positioned between the molecular lines and bonded to the side of an organic monomer within one of the molecular lines and comprising a metal atom, and a crosslinking functional group bonded to the side of the organic monomer within the other molecular line. Upon radiation exposure, the unreacted terminal functional group of the side inorganic monomer further reacts with the organic monomer, resulting in crosslinking, thereby forming a photoresist pattern with excellent etch resistance.

### DESCRIPTION OF DRAWINGS

FIG. 1 is a schematic diagram showing a multilayer molecular film photoresist having a vertical molecular line structure according to an embodiment of the present invention.

FIG. 2 is a schematic diagram illustrating a multilayer molecular film photoresist having a vertical molecular line structure according to one embodiment of the present invention.

FIG. 3 is a schematic diagram showing an apparatus for manufacturing a multilayer molecular film photoresist having a vertical molecular line structure according to an embodiment of the present invention.

FIGS. 4 to 7 are schematic diagrams sequentially illustrating a photolithography method according to an embodiment of the present invention.

FIG. 8 illustrates a multilayer molecular film photoresist having a vertical molecular line structure formed according to Manufacturing Example 1.

FIG. 9 shows graphs showing the film growth rate according to the supply time of each precursor when manufacturing a photoresist according to Manufacturing Example 1.

FIG. 10 shows a graph showing the change in film thickness according to the number of cycles of the photoresist according to Manufacturing Example 1, along with an AFM image of the surface.

FIG. 11 shows an SEM image taken after patterning the photoresist obtained in Manufacturing Example 1.

FIG. 12 is a schematic diagram illustrating crosslinking within the photoresist during the exposure process of FIG. 11.

FIG. 13 is a graph showing the electron beam sensitivity of the photoresist obtained in Manufacturing Example 1.

FIG. 14 is a schematic diagram illustrating the EUV irradiation pattern and dose conditions, and

FIG. 15 is an optical photograph of the photoresist patterns obtained after irradiating the photoresist according to Manufacturing Example 1 with the EUV pattern illustrated in FIG. 14.

FIG. 16 is a graph showing the change in film thickness according to the number of cycles for the photoresist according to Manufacturing Example 2, along with an AFM image of the surface.

FIG. 17 is a graph showing the change in film thickness according to the number of cycles for the photoresist according to Manufacturing Example 3, along with an AFM image of the surface.

### MODES OF THE INVENTION

In this specification, metal may include all metals, but as an example, it may be a transition metal, a post-transition metal, or a metalloid.

In this specification, the radiation may be EUV or E-beam, as an example. However, in some cases, it is not limited to this.

In this specification, a monomer refers to a molecule that is not a polymer, and as an example, the monomer refers to a small molecule, specifically, a molecule having 100 or less atoms, and specifically, 30 or less atoms.

In this specification, molecules or functional groups “connected by a bond” may mean that they are directly connected or indirectly connected by placing other molecule(s) or functional groups between them.

In this specification, when “CX to CY” is written in this specification, it should be interpreted as the numbers corresponding to all integers between carbon number X and carbon number Y are also written. For example, when C1 to C10 are described, it should be interpreted as C1, C2, C3, C4, C5, C6, C7, C8, C9, and C10 are all described.

In this specification, when “X to Y” is written in this specification, it should be interpreted as the numbers corresponding to all integers between X and Y are also written. For example, when 1 to 10 are written, it should be interpreted as 1, 2, 3, 4, 5, 6, 7, 8, 9, and 10 are all written.

In this specification, when referred to as an “aromatic ring”, it is an aromatic ring of 5 to 12 members, specifically 5 to 6 members, and has a homocyclic structure in which the constituent members are all carbon or heterocyclic structure in which some of the constituent members are substituted with heteroelements.

As used herein, the “alkylene group” or “alkyl group” may have all elements constituting the main chain of carbon, or some carbon may be substituted with O, S, N, C═O, or Si. The substituted element is not limited to this.

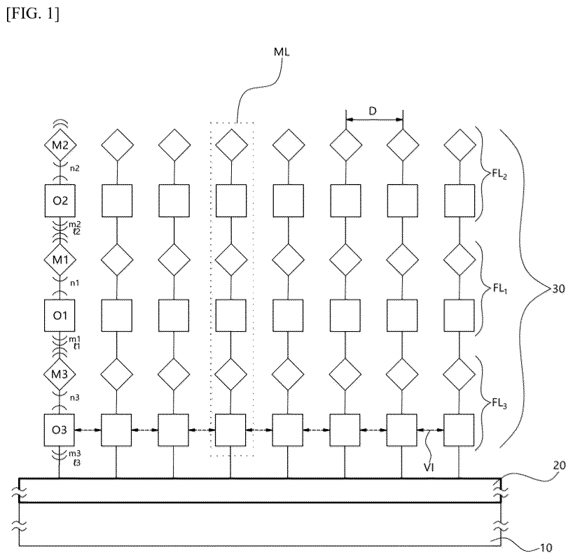

FIG. 1 is a schematic diagram showing a multilayer molecular film photoresist having a vertical molecular line structure according to an embodiment of the present invention.

Referring to FIG. 1, a substrate 10 may be provided. The substrate may be a bare substrate such as a semiconductor substrate, a glass substrate, or a flexible substrate. For example, the flexible substrate may be a polymer substrate. On the substrate, at least one device (not shown) such as a transistor, memory, diode, solar cell, optical device, biosensor, nanoelectromechanical system (NEMS), microelectromechanical system (MEMS), nanodevice, or chemical sensor may have been formed. The device may be an organic electronic device such as an organic light-emitting diode or an organic solar cell. As such, in this embodiment, the substrate 10 may be the bare substrate, or a substrate including the device formed on the bare substrate.

An etch target layer 20 may be formed on the substrate 10. The etch target layer 20 is a layer that will be etched to form a pattern using a photoresist pattern as an etch mask after forming the photoresist pattern on the layer 20, and may be formed of various materials used in the semiconductor process. As an example, the etch target layer 20 may be a metal film, a semiconductor film, an insulating film, or a composite film containing any one of these. The metal film may be used to form wiring, and may be aluminum, tungsten, titanium, or a composite film containing any one of these. The semiconductor film may be a silicon film, for example, a single crystal silicon film, a polysilicon film, an amorphous silicon film, or a composite film containing any one of these. The insulating film may include an inorganic insulating film such as a silicon oxide film or a silicon nitride film; an organic insulating film such as an amorphous carbon film; or a composite film containing any one of these. In one example, the etch target layer 20 may be the bare substrate.

The etch target layer 20 may have a hydroxyl group, a thiol group, an amine group, or a phosphine group as an example of a surface functional group, or may be surface-treated to have the same.

A multilayer molecular film photoresist 30 having a molecular line structure may be formed on the etch target layer 20. Specifically, the multilayer molecular film photoresist 30 may have a plurality of molecular lines ML that individually extend upwardly from the substrate 10 and are arranged laterally. In one example, the molecular lines ML may extend upwardly from the substrate 10, for example, in a vertical direction to the substrate 10, and the lateral direction of the lateral arrangement can be a direction substantially parallel to the surface of the substrate.

Each molecular line ML may include linearly connected monomers, and the monomers may include a plurality of main inorganic monomers M1, M2, M3 including metal atoms and organic monomers O1, O2, O3 interposed between at least some of the main inorganic monomers. Such a multilayer molecular film photoresist 30 may be referred to as an organic-inorganic multilayer molecular film photoresist. In the present specification, the molecular line ML may be defined as a backbone, molecular chain, or chain formed by main inorganic monomers and organic monomers that are linearly connected by bonds. The bonds may be covalent bonds or coordinate bonds.

In one example, it may further include a side inorganic monomer (not shown) positioned between the molecular lines ML and bonded to the side of the organic single molecule O1, O2, O3. In the present specification, the side may be a region intersecting the direction of extension of the molecular line ML specifically, intersecting the upper direction of the substrate and parallel to the substrate. The main inorganic monomers, or the main inorganic monomer and the organic monomer, may be connected to another monomer by one bond selected from the group consisting of —O—, —S—, —Se—, —NR— (R is H or CH₃) and —PR— (R is H or CH₃) contained in one of the adjacent monomers. In addition, the organic monomer and the side inorganic monomer, may be linked to the other monomer by a bond selected from the group consisting of —O—, —S—, —Se—, —NR— (R is H or CH₃) and —PR— (R is H or CH₃) contained in either monomer. However, the present invention is not limited thereto, and the monomers may be linked indirectly by bonds through additional functional groups.

In this embodiment, the multilayer molecular film photoresist 30 may be formed using Atomic Layer Deposition or Molecular Layer Deposition, so that almost all molecular lines ML in the multilayer molecular film photoresist 30 may have substantially the same stacked structure. As a result, the molecular lines ML in the multilayer molecular film photoresist 30 may have substantially the same inorganic monomers located at the same level and substantially the same organic monomers located at the same level. Therefore, the inorganic monomers located at the same level of the molecular lines ML may form an inorganic monomolecular layer in the horizontal direction; and the organic monomers located at the same level of the molecular lines ML may form an organic monomolecular layer in the horizontal direction.

In addition, the molecular lines ML may be formed so that the gap D between adjacent molecular lines ML is sufficiently narrow so that van der Waals interactions VI appear between organic monomers O1, O2, O3 within adjacent molecular lines ML. The van der Waals interactions VI may stabilize the laterally adjacent molecular lines ML to prevent the pattern from collapsing even when the aspect ratio is high, and may enable the molecular lines ML to extend substantially perpendicularly to the substrate 10. In one example, the van der Waals interactions may be interactions between alkylene groups or π-π bonds between aromatic groups provided in the organic monomers O1, O2, O3.

The multilayer molecular film photoresist 30 may have a structure represented by the following Chemical Formula 1.

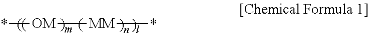

In Chemical Formula 1, one of the *s may be a bond to a functional group in an underlying layer or a functional group in an underlying monomer, and the other one may be a bond to a functional group in an upper layer or a functional group in an upper monomer. The bond may be, for example, a covalent bond. In Chemical Formula 1, m may be 0 to 10, n may be 1 to 10, and l may be 1 to 10000, specifically 20 to 1000, and more specifically 25 to 100. Specifically, m may be 1 to 2, and as an example, m may be 1. n may also be 1 to 2, for example, n may be 1. OM may be an organic monomer, and MM may be a main inorganic monomer. A detailed explanation of these will be provided later. Chemical Formula 1 may mean that the organic monomer OM and the main inorganic monomer MM are sequentially stacked on the underlying layer, and also mean that main inorganic monomer MM and organic monomer OM are sequentially stacked on the underlying layer.

In FIGS. 1, O1, O2, and O3 are all organic monomers OM, which may be different organic monomers or the same organic monomers. In addition, in FIG. 1, M1, M2, and M3 are all main inorganic monomers MM, which may be different inorganic monomers or the same inorganic monomers. In addition, in FIG. 1, n1, n2, and n3 are equal to the value defined as n in the Chemical Formula 1 regardless of each other, m1, m2, and m3 are equal to the value defined as m in the Chemical Formula 1 regardless of each other, and l1, l2, and l3 are equal to the value defined as l in the Chemical Formula 1 regardless of each other.

In one example, the multilayer molecular film photoresist 30 may include at least one layer among a light-absorbing layer FL₁, a light-reactive layer FL₂, and an etching-resistant layer FL₃, which are distinguished according to the main function of the main inorganic monomer, specifically, the main function of the metal atom provided in the main inorganic monomer. As an example, the multilayer molecular film photoresist 30 may include one type of layer, two types of layers, or three types of layers among these layers. The stacking order of the light-absorbing layer FL₁, the light-reactive layer FL₂, and the etching-resistant layer FL₃ may vary depending on the type of the etch target layer 20 and/or the type of pattern to be formed through photolithography. Meanwhile, the light-absorbing layer FL₁, the light-reactive layer FL₂, and the etching-resistant layer FL₃ can all basically perform secondary electron generation and photoreaction according to light absorption.

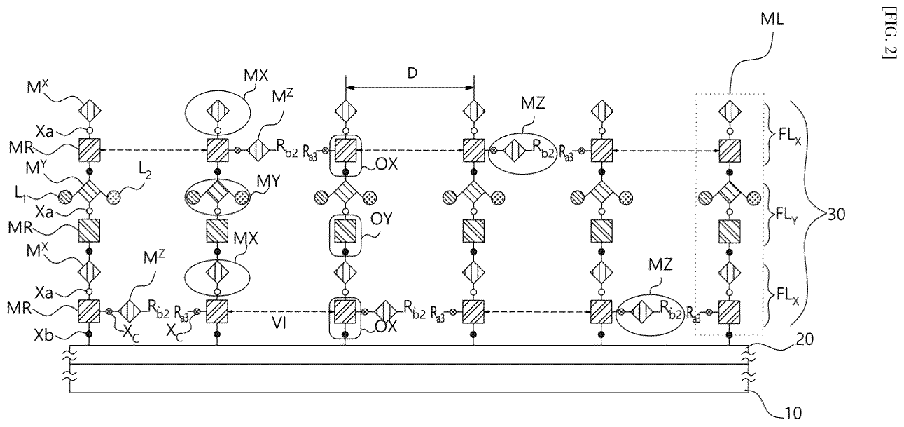

FIG. 2 is a schematic diagram illustrating a multilayer molecular film photoresist having a vertical molecular line structure according to one embodiment of the present invention.

Referring to FIG. 2, molecular lines ML of the multilayer molecular film photoresist 30 may include linearly connected main inorganic monomers and organic monomers represented by Chemical Formula 1, and in some cases, the molecular lines ML include linearly connected main inorganic monomers and organic monomers represented by Chemical Formula 2. In FIG. 2, l, m, and n of Chemical Formula 1 are all 1, MM is represented by MX or MY, and OM is represented by OX or OY Side inorganic monomers MZ may connect to sides of some of the organic monomers.

The main inorganic monomer (MM, MX, or MY in Chemical Formula 1) may be a metal-containing inorganic monomer, specifically an organometallic monomer. As an example, the main inorganic monomer may be a light-absorbing inorganic monomer containing a metal element having a d orbital, a photoreactive inorganic monomer containing Zr, Al, Hf, Zn, or In, or an etch-resistant inorganic monomer containing Al, Ti, Cu, W, Si, or Zn. The metal element having the d orbital, specifically 4d or 5d orbital, may be Sn, Sb, Te, or Bi. Although inorganic monomers have been classified by distinct functions, all of the described inorganic monomers may be capable of light-absorbing and photoreaction.

Specifically, the main inorganic monomer MM, MX, MY may be an organometallic monomer having at least two organic functional groups or ligands, and may be bonded to a lower layer or a lower monomer, specifically the organic monomer OM, via a linker Xₐ such as O, S, Se, NR (R is H or CH₃) or PR (R is H or CH₃) bonded directly or indirectly to one end thereof. The main inorganic monomer MM, MX, MY may be an organometallic monomer represented by the following Chemical Formula 2.

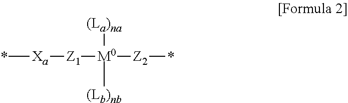

In Formula 2, one of the *s may be a bond with a functional group in an underlying layer or an underlying organic or inorganic monomer (specifically its functional group), and the other one may be a bond with a functional group in the upper layer or an upper organic or inorganic monomer (specifically its functional group). The bond may be, for example, a covalent bond. Z₁ and Z₂ may be, regardless of each other, a bond, a substituted or unsubstituted linear or branched alkylene group of C1 to C20, a substituted or unsubstituted linear or branched alkyleneoxide of C1 to C20, a substituted or unsubstituted linear or branched alkyleneamino of C1 to C20, a substituted or unsubstituted linear or branched alkylenesilylamino of C1 to C20, a substituted or unsubstituted linear or branched alkylenethio of C1 to C20, a substituted or unsubstituted linear or branched alkyleneseleno of C1 to C20, or a substituted or unsubstituted linear or branched alkylenephosphino of C1 to C20. M⁰ may be a light-absorbing metal atom having a d orbital, a photoreactive metal atom of Zr, Al, Hf, Zn, or In, or an etch-resistant metal atom of Al, Ti, Cu, W, or Zn. The metal element having the d orbital, specifically a 4d or 5d orbital, may be Sn, Sb, Te, or Bi. Xₐ may be O, S, Se, NR (R may be H or CH₃) or PR (R may be H or CH₃).

Lₐ and L_{b} are functional groups bonded to M⁰. The sum of na and nb, the number of Lₐ and L_{b}, may be determined by the maximum coordination number of M⁰, and may be less than or equal to the number minus 2 (the number considering Z₁ and Z₂) from the maximum coordination number. For example, the sum of na and nb may be an integer from 0 to 4. Lₐ and L_{b}, regardless of each other, may be a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted, linear or branched alkyl groups. Additionally, in Formula 2, when na and/or nb are 2 or more, Lₐ and/or L_{b} may be selected, regardless of each other, among the above examples. In one example, when the sum of na and nb is 2 or more, two of Lₐ and L_{b} may be combined with M⁰ to which they are attached to form heterocyclyl or heteroaryl. Each bond between Z₁, Z₂, Lₐ, or L_{b} and M⁰ may be covalent or coordinate bond, regardless of the other.

Referring to FIG. 2, M^{X} and M^{Y} correspond to M⁰ in Chemical Formula 2. The main inorganic monomer MX is an exemplary representation of a case where both na and nb are 0 and Z₁ and Z₂ are direct bonds. Similarly, the main inorganic monomer MY is an exemplary representation of a case where both na and nb are 1 and Z1 and Z2 are direct bonds.

The side inorganic monomer MZ may be represented by the following Chemical Formula 3.

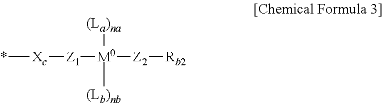

In Chemical Formula 3, X_{c} may be O, S, Se, NR (where R is H or CH₃), or PR (where R is H or CH₃). In one example, X_{c} may be S. R_{b2} may be a halogen group (e.g., Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. Z₁, Z₂, Lₐ, L_{b}, na, nb, and M₀ are as defined in Chemical Formula 2. In some cases, two of R_{b2}, Lₐ, and L_{b}, together with M⁰ to which they are directly or indirectly bonded, may combine to form a heterocyclyl or a heteroaryl. In some cases, R_{b2} can be in a state of coordination bonding to M⁰. In the side inorganic monomer MZ shown in FIG. 2, M^{Z} corresponds to M⁰ in Chemical Formula 3 and represents the case where both na and nb are 0 and both Z₁ and Z₂ are direct bonds.

In FIG. 2, the Z₁, Z₂, Lₐ, L_{b}, na, nb, and M⁰ of the main inorganic monomer MX bonded to the upper part of the organic monomer OX may each be identical to the Z₁, Z₂, Lₐ, L_{b}, na, nb, and M⁰ of the side inorganic monomer MZ bonded to the side of the organic monomer OX. This may be attributed to the fact that the main inorganic monomer MX bonded to the upper part of the organic monomer OX and the side inorganic monomer MZ bonded to the side of the organic monomer OX are formed in the same step using the same metal precursor.

Organic monomers (OM in Chemical Formula 1, OX and OY in FIG. 2) may have a linear chain with 2 to 7 carbons or a non-aromatic or aromatic ring with 3 to 18 carbons as their body. Some of the carbons may be substituted with an element selected from the group consisting of C═O, N, S, O, and Si. The linear chain can extend in substantially the same direction as the molecular line ML. The major axis of the ring can be in substantially the same direction as the extension direction of the molecular line ML. The organic monomer (OM in Chemical Formula 1, OX and OY in FIG. 2) may be bonded to a lower layer (specifically, a lower main inorganic monomer) through a linking functional group X_{b} bonded directly or indirectly to the lower part of the body, specifically —O—, —S—, —Se—, —NR— (where R is H or CH₃), or —PR— (where R is H or CH3).

In one example, some of the organic monomers (OM in Chemical Formula 1, OX in FIG. 2) may have an amide group or an amine group within the linear chain or ring. When a side inorganic monomer (MZ in Chemical Formula 2, where x is 1 or more) is bonded to the organic monomer, the amide group or amine group, which is —NR— (where R is H or CH₃), may act as a linking functional group X_{c} to which a metal atom M^{Z} may be bonded. In another example, a cross-linking functional group (—Z₅X_{c}Rₐ₃, where Z₅ is a direct bond in FIG. 2) or a side inorganic monomer (MZ, —Z₅X_{c}M^{Z}R_{b2}, where Z₅ is a direct bond in FIG. 2) may be bonded to the side of the body of the organic monomer (OM in Chemical Formula 1, OX in FIG. 2). In this case, the linking functional group X_{c} may be O, S, Se, NR (where R is H or CH₃), or PR (where R is H or CH₃).

As one example, the organic monomers OM in Chemical Formula 1, and OX and OY in FIG. 2, may be organic monomers represented by the following Chemical Formula 4.

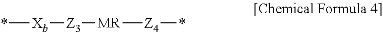

In Chemical Formula 4, one of the asterisks (*) may be a bond with a functional group of an underlying layer or a lower monomer (e.g., a lower main inorganic monomer) in the molecular chain, while the other may be a bond with a functional group of an upper layer or an upper monomer (e.g., upper main inorganic monomer) in the molecular chain. The bond may be, for example, a covalent bond. X_{b} may be O, S, Se, NR (where R is H or CH₃), or PR (where R is H or CH₃). In one example, X_{b} may have a higher reactivity compared to Xₐ or X_{c}, and may be, for example, O or S. Z₃ and Z₄ may be, independently of each other, a direct bond or a linear or branched alkylene group of C1 to C5. Here, the substitution may be one in which a hydrogen of the alkylene group is substituted with various functional groups, for example, OH, SH, SeH, NR₂ (where R is independently H or CH₃), or PR₂ (where R is independently H or CH₃).

In one example, the MR in Chemical Formula 4 may have a linear chain with 2 to 7 carbons or a non-aromatic or aromatic ring with 3 to 18 carbons as its body. Some of the carbons may be substituted with an element selected from the group consisting of C═O, N, S, O, and Si. The linear chain may be, for example, a linear alkylene group of C3 to C7, specifically C3 to C5. The linear chain may be substituted with a C1 to C2 alkyl group. In the case that MR is a linear chain, Z₃ and Z₄ may be a direct bond.

In one example, a cross-linking functional group, —(Z₅X_{c}Rₐ₃)ₓ, may be bonded to the MR of at least some of the organic monomers. Here, Z₅ may be a direct bond or a substituted or unsubstituted, linear or branched alkylene group of C1 to C5, specifically C1 to C3. X_{c} may be O, S, Se, NR (where R is H or CH₃), or PR (where R is H or CH₃). In one example, X_{c} may be S. Rₐ₃ may be a hydrogen or a C1 to C2 alkyl group. In one example, Z₅ may be a direct bond, in which case X_{c} may be directly bonded to MR. The value of x may be 1 to 2. The side functional group, —Z₅X_{c}Rₐ₃, may be bonded to a carbon within MR, or to an N or Si atom that is included by substituting a carbon. When multiple —Z₅X_{c}Rₐ₃ groups are bonded to the same member of MR, their number (x) may be limited to the number of available covalent bonds of that member. FIG. 2 exemplarily shows a case where x is 1 and Z₅ is a direct bond in —(Z₅X_{c}Rₐ₃)ₓ. In another example, the chain of the MR may have an amide group or an amine group.

In addition, a side inorganic monomer MZ represented by the aforementioned Chemical Formula 4 may be bonded to the MR of at least some of the organic monomers.

In FIG. 2, OX is an organic monomer provided within the first layer FL_{X}, which is an exemplary representation of an organic monomer bonded with the cross-linking functional group (—(Z₅X_{c}Rₐ₃)ₓ, where x=1 and Z₅ is a direct bond) or a side inorganic monomer MZ. OY is an organic monomer provided within the second layer FL_{Y}, which is an exemplary representation of an organic monomer to which the cross-linking functional group or side inorganic monomer is not bonded.

The multi-layer molecular film photoresist 30 may have a structure in which main inorganic monomers MM and organic monomers OM are alternately laminated. In this case, the organic monomers OM are arranged alternately between the main inorganic monomers MM, allowing the main inorganic monomers MM and the organic monomers OM to self-assemble. As a result, the molecular lines ML can each extend in an upward direction, for example, in a vertical direction, relative to the substrate 10, while being arranged spaced apart from each other.

The van der Waals interaction VI between the organic monomers OM within mutually adjacent molecular lines ML can stabilize the laterally adjacent molecular lines ML, preventing the pattern from collapsing even when it has a high aspect ratio.

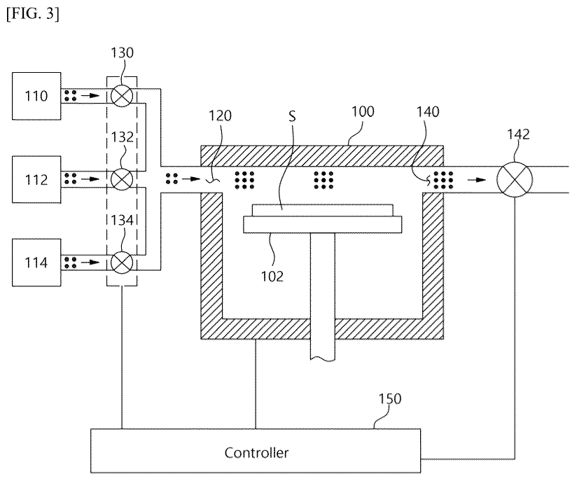

FIG. 3 is a schematic diagram showing an apparatus for manufacturing a multilayer molecular film photoresist having a vertical molecular line structure according to an embodiment of the present invention.

Referring to FIGS. 2 and 3 simultaneously, a substrate S may be loaded on a stage 102 in a chamber 100 having a gas inlet 120 and a gas outlet 140. The substrate S may be the substrate 10 on which an etch target layer 20 described with reference to FIG. 1 is formed.

Before loading the substrate S, the chamber 100 may be heated and maintained at a deposition temperature by the controller 150. The deposition temperature may be 20 to 250° C., 50 to 200° C., 80 to 150° C., 90 to 140° C., or 100 to 130° C. The gas outlet 140 may be connected to a vacuum pump.

First, a vacuum inside the chamber 100 may be created by closing all the gas inlet valves 130, 132, and 134 connected to the gas inlet 120 and opening the gas outlet valve 142 connected to the gas outlet 140.

Thereafter, the multilayer molecular film photoresist 30 may be formed by performing a cycle including the step of forming a main inorganic monomer layer (MM in Chemical Formula 1, specifically MX or MY in FIG. 2) and the step of forming an organic monomer layer (OM in Chemical Formula 1, specifically OX or OY in FIG. 2). The step of forming the inorganic monomer layer and the step of forming the organic monomer layer can be performed using atomic layer deposition, specifically, molecular layer deposition. In the present specification, a unit cycle of forming an inorganic monomer layer after forming an organic monomer layer is described, but this concept is to be construed as including the formation of an organic monomer layer after forming an inorganic monomer layer when performing the unit cycle.

In the step of forming the organic monomer layer (OM in Chemical Formula 1, specifically OX or OY in FIG. 4), an organic monomer layer unit cycle can be performed. The organic monomer layer unit cycle may comprise an organic precursor dosing step of dosing an organic precursor and chemically bonding the organic precursor to the lower layer in a self-assembly manner; and a purge step of supplying a purge gas to purge unreacted organic precursors and reaction by-products.

The organic precursor may have a body with a linear chain having 2 to 7 members or a non-aromatic or aromatic ring having 3 to 18 members. Each member may be selected from the group consisting of C, C═O, N, S, O, and Si. The organic precursor may have ORₐ₁, SRₐ₁, SeRₐ₁, NRRₐ₁ (R may be H or CH₃) or PRRₐ₁ (R may be H or CH₃) directly or indirectly bonded to one end of the body, and ORₐ₂, SRₐ₂, SeRₐ₂, NRRₐ₂ (R may be H or CH₃) or PRRₐ₂ (R may be H or CH₃) directly or indirectly bonded to the other end of the body. Rₐ₁ and Rₐ₂ may be hydrogen or a C1 to C2 alkyl group regardless of each other. In addition, the organic precursor may have an amide group or an amine group within the linear chain or ring. In another example, the organic precursor may further include a cross-linking functional group on a side branch of its linear chain body, such as ORₐ₃, SRₐ₃, SeRₐ₃, NRRₐ₃ (R may be H or CH₃) or PRRₐ₃ (R may be H or CH₃). Rₐ₃ may be a hydrogen or a C1 to C2 alkyl group.

In one example, the organic precursor may be represented by Chemical Formula 5 below.

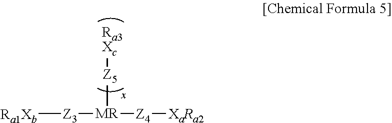

In Chemical Formula 5, Rₐ₁ and Rₐ₂ may be hydrogen or a C1 to C2 alkyl group regardless of each other, and X_{b} and Xₐ may be O, S, Se, NR (R may be H or CH₃) or PR (R may be H or CH₃) regardless of each other. As an example, X_{b} may be O and Xₐ may be S. Meanwhile, Z₃, Z₄, and MR are as defined in Chemical Formula 4 above.

—(Z₅X_{c}Rₐ₃)ₓ acts as a cross-linking functional group. Z₅ may be a direct bond or a substituted or unsubstituted, linear or branched C1 to C5 (specifically C1 to C3) alkylene group. X_{c} may be O, S, Se, NR (where R is H or CH₃), or PR (where R is H or CH₃). In one example, X_{c} can be S. Rₐ₃ can be a hydrogen or a C1 to C2 alkyl group. In one example, Z₅ may be a direct bond, in which case X_{c} may be directly bonded to MR. The value of x can be from 0 to 2. When x is from 1 to 2, the cross-linking functional group, —Z₅X_{c}Rₐ₃, may be bonded to a member within MR, specifically to C, N, or Si. If the cross-linking functional groups, —(Z₅X_{c}Rₐ₃)ₓ, are bonded to the same carbon atom in MR, the number (x) is limited to the number of available covalent bonds of that carbon. In cases where n in Chemical Formula 2 is 0, the chain of MR can have an amide group or an amine group. In another example, when n in Chemical Formula 2 is 0, MR can be composed solely of carbons. FIG. 2 shows an example where x is 1 and Z₅ is a direct bond in —(Z₅X_{c}Rₐ₃)ₓ.

Examples of the organic precursor may be as follows, in cases where x is 1 in Chemical Formula 5, or where x is 0 and an amide group or an amine group is provided as a reactive functional group within MR:

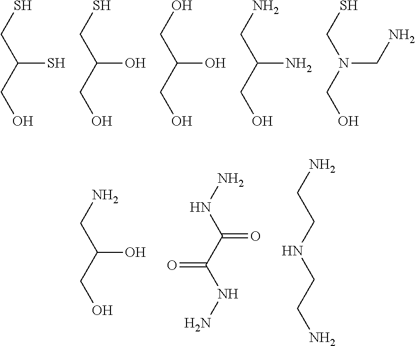

Examples of the organic precursor can be as follows, in cases where x is 0 in Chemical Formula 5 and no reactive functional group, such as an amide or an amine group, is provided within MR.

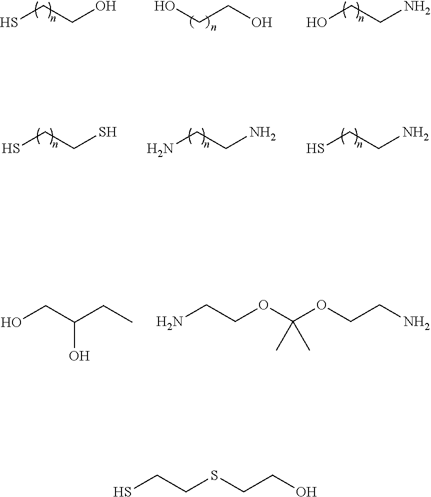

n may be from 1 to 2 in the above organic precursors.

In the organic precursor dosing step, a reaction according to the following Reaction Scheme 1 may occur.

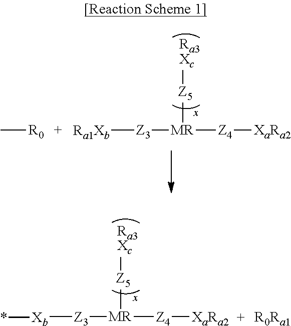

In Reaction Scheme 1, R₀ may be a functional group on the surface of the underlying layer or a lower monomer, specifically a surface functional group of a lower main inorganic monomer (R_{b2} in the following Reaction Scheme 2). R₀ may be hydrogen, a hydroxy group, a thiol group, an amine group, a phosphine group, a C1 to C5 alkyl group, a C1 to C5 alkoxy, a C1 to C5 alkylthio group, a C1 to C5 alkylseleno group, a C1 to C5 alkylamine group, or a C1 to C5 alkylphosphino group. Rₐ₁X_{b}—Z₃-MR(—Z₅—X_{c}Rₐ₃)ₓ(—Z₄—XₐRₐ₂) is an organic precursor, and each functional group is as defined in Chemical Formula 5 above. When X_{b} and Xₐ are different from each other, the more reactive functional group may combine with the surface functional group of the underlying layer. As an example, when X_{b} and Xₐ are O and S, respectively, O may combine with the surface functional group of the underlying layer. X_{c} may also be a functional group with lower reactivity compared to X_{b}, which bonds to the lower layer surface functional group. such as S.

Referring to the aforementioned Reaction Scheme 1, the organic precursor may react with a functional group on the surface of the underlying layer to self-assemble onto the underlying layer. In this process, R₀Rₐ₁ may be produced as a reaction by-product. Thereafter, during the purge step, the remaining excess organic precursors and the aforementioned reaction by-products may be purged.

In the organic precursor dosing step, the organic precursor may be supplied from the organic precursor storage unit 114 into the chamber 100 with the organic precursor control valve 134 opened and the gas outlet valve 142 closed (organic precursor supply step). The organic precursor within the organic precursor storage unit 114 may be stored in a solid, liquid, or gaseous state. The organic precursor storage unit 114 may be heated and the organic precursor may be supplied into the chamber 100 at a predetermined vapor pressure. In one embodiment, the organic precursor may be supplied without a carrier gas. In other words, the organic precursor alone may be supplied into the chamber 100.

Since the organic precursor is supplied with the gas outlet valve 142 closed, it may accumulate in the chamber 100 and increase the pressure within the chamber 100. The organic precursor may be supplied until the pressure of the chamber 100 reaches the reaction pressure (organic precursor supply step). The reaction pressure may be the pressure of the organic precursor alone in the chamber 100, and may be in the range of 10 mTorr to 10 Torr, specifically 50 mTorr to 10 Torr, 100 mTorr to 6 Torr, 130 mTorr to 3 Torr, or 150 mTorr to 1 Torr. Typically, the precursor is dosed into the chamber along with a carrier gas, and considering that the partial pressure of the precursor in this case is about 1 to 10 mTorr, a pressure greater than 50 mTorr of the pressure of the organic precursor alone in chamber 100 may mean that the organic precursor may be in a pressurized state in the chamber 100.

When the reaction pressure is reached, the organic precursor control valve 134 may be closed, and the chamber may be sealed for a predetermined period of time while the gas outlet valve 142 is closed (organic precursor exposure step). The organic precursor supply step and the organic precursor exposure step may be referred to as an organic precursor dosing step. However, the organic precursor exposure step may be omitted in some cases. In the organic precursor dosing step, the reaction according to Reaction Scheme 1 may occur.

After this, the chamber 100 may be purged (organic precursor purge step). Specifically, the purge gas control valve 132 and the gas outlet valve 142 are opened to flow the purge gas in the purge gas storage unit 112 onto the surface of the substrate to remove unreacted excess organic precursor and the reaction by-products. The purge gas may be an inert gas, and the inert gas may include, for example, argon (Ar), nitrogen (N₂), or a combination thereof.

In the step of forming the inorganic monomer layer (MM in Chemical Formula 1, specifically MX or MY in FIG. 4), a unit cycle can be performed. The unit cycle may comprise an inorganic precursor dosing step of dosing an inorganic precursor and chemically bonding the inorganic precursor to an underlying layer in a self-assembly manner; and a purge step of supplying a purge gas to purge unreacted inorganic precursors and reaction by-products.

The inorganic precursor may be an organometallic monomer having at least two organic functional groups or ligands. The inorganic precursor may be represented by the following Chemical Formula 6.

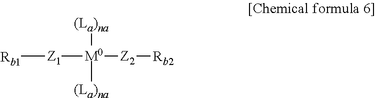

In Chemical Formula 6, R_{b1} and R_{b2} are, regardless of each other, a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted linear or branched alkyl groups. Z₁, Z₂, Lₐ, L_{b}, na, nb, and M⁰ are as defined in Chemical Formula 2. In addition, in some cases, two of R_{b1}, R_{b2}, Lₐ, and L_{b} may be combined with M⁰ to which they are directly or indirectly bonded to form heterocyclyl or heteroaryl. In some cases, at least one of R_{b1} and R_{b2} may be in a state of coordination bonding to M⁰.

As an example, Z₁ and Z₂ may be bonds, and Lₐ, L_{b}, R_{b1}, and R_{b2} may be the same functional groups. As another example, Z₁ and Z₂ may be bonds, Lₐ and L_{b} may be the same functional groups, and R_{b1} and R_{b2} may be the same functional groups, but Lₐ and R_{b1} may be different functional groups.

Examples of the aforementioned inorganic precursor may be as follows.

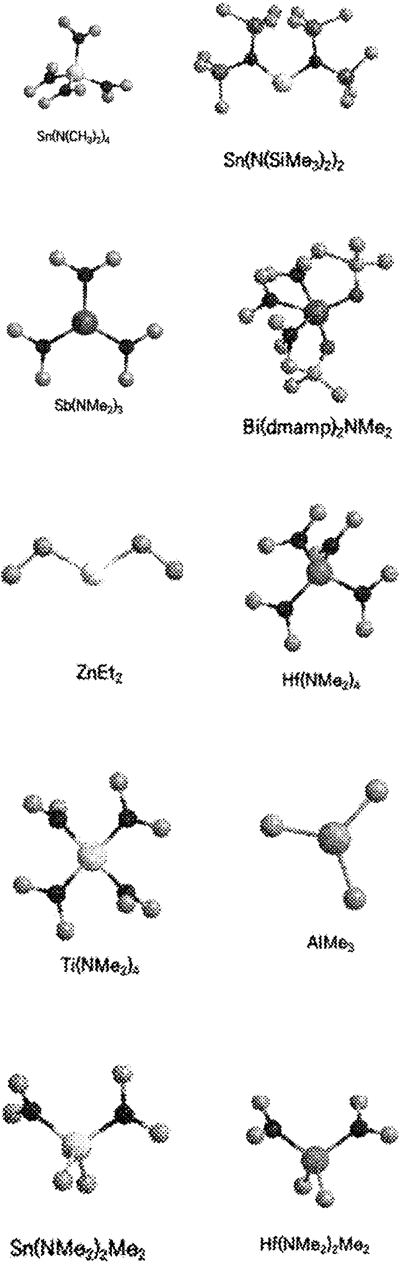

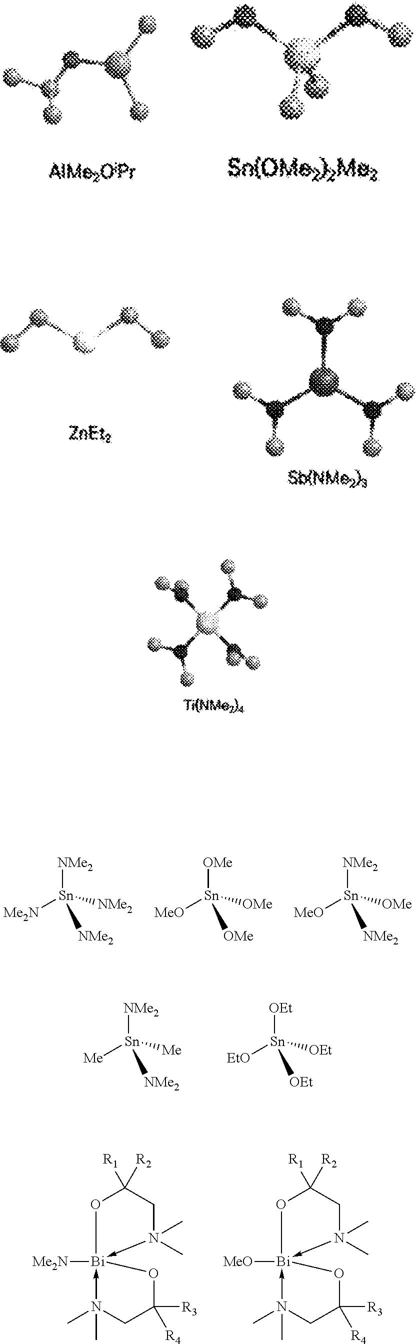

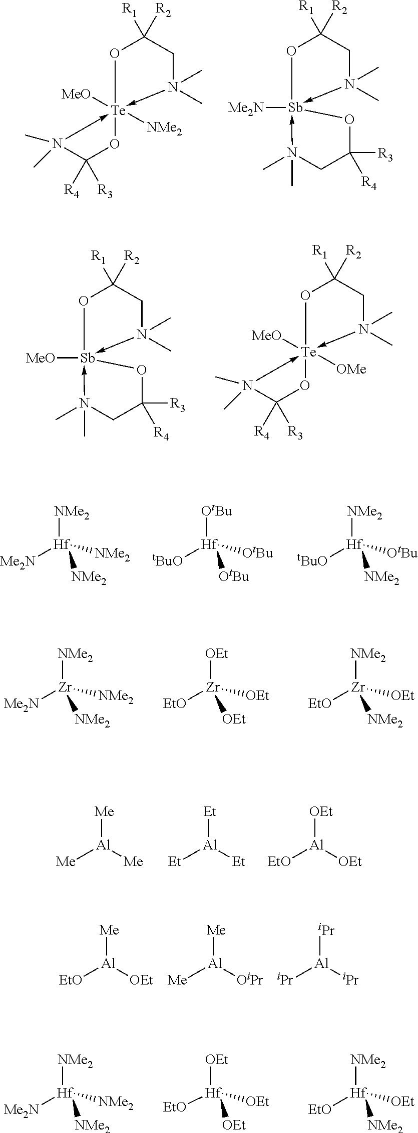

In the aforementioned metal precursors, dmamp refers to 1-dimethylamino-2-methyl-2-propoxy, and R₁, R₂, R₃, and R₄ may each independently be a C1 to C5 alkyl group.

In the inorganic precursor dosing step, the inorganic precursor gas may be supplied from the inorganic precursor storage unit 110 into the chamber 100 with the inorganic precursor gas control valve 130 opened and the gas outlet valve 142 closed (inorganic precursor supply step). The inorganic precursor within the inorganic precursor storage unit 110 may be stored in a solid, liquid, or gaseous state. The inorganic precursor storage unit 110 may be heated below the thermal decomposition temperature of the inorganic precursor, and thus the inorganic precursor can be supplied into the chamber 100 at a predetermined vapor pressure. The inorganic precursor may be supplied without a carrier gas. In other words, the inorganic precursor alone may be supplied into the chamber 100.

Since the inorganic precursor is supplied with the gas outlet valve 142 closed, the inorganic precursor may accumulate in the chamber 100 and increase the pressure within the chamber 100. The inorganic precursor may be supplied until the pressure of the chamber 100 reaches the reaction pressure (inorganic precursor supply step). The reaction pressure may be the pressure of the inorganic precursor alone in the chamber 100 in the range of 10 mTorr to 10 Torr, specifically 50 mTorr to 10 Torr, 100 mTorr to 6 Torr, 600 mTorr to 5 Torr, or 700 mTorr to 2 Torr. Typically, the precursor is dosed into the chamber along with a carrier gas, and considering that the partial pressure of the precursor in this case is about 1 mTorr, a pressure of 50 mTorr or more of the inorganic precursor alone in the chamber 100 indicates that the inorganic precursor may be in a pressurized state.

When the reaction pressure is reached, the inorganic precursor gas control valve 130 may be closed and the chamber may be sealed for a predetermined period of time (inorganic precursor exposure step). The inorganic precursor supply step and the inorganic precursor exposure step may be referred to as an inorganic precursor dosing step. However, the inorganic precursor exposure step may be omitted in some cases. In the inorganic precursor dosing step, a reaction according to Reaction Scheme 2 may occur, and in some cases, a reaction according to both Reaction Scheme 2 and Reaction Scheme 3 may occur.

After this, the chamber 100 may be purged (inorganic precursor purge step). Specifically, the purge gas control valve 132 and the gas outlet valve 142 are opened to allow the purge gas in the purge gas storage unit 112 to flow onto the surface of the substrate in the chamber to remove excess inorganic precursor gas that is not adsorbed on the surface of the substrate and the reaction by-products. The purge gas is an inert gas, and the inert gas may include, for example, argon (Ar), nitrogen (N₂), or a combination thereof.

In the inorganic precursor dosing step, a reaction according to Reaction Scheme 2 below may occur.

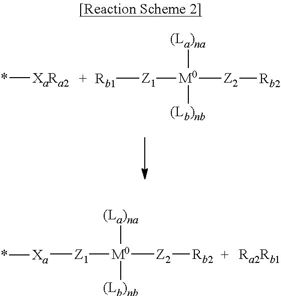

In Reaction Scheme 2, *—XₐRₐ₂ is a surface functional group of the underlying layer, specifically the surface functional group of the previously formed organic monomer OM. The inorganic precursor in Chemical Formula 6 may react with the surface functional group of the previously formed organic monomer OM to self-assemble onto the surface of the organic monomer OM. In this process, Rₐ₂R_{b1} may be generated as a reaction by-product. Thereafter, in the purge step, the remaining inorganic precursors and the aforementioned reaction by-products may be purged. In Reaction Scheme 2, each functional group may be the same as defined in Reaction Scheme 1 and Chemical Formula 6.

In another example of the inorganic precursor dosing step, in addition to the reaction according to Reaction Scheme 2, a reaction according to the following Reaction Scheme 3 may occur. This may be the case when the organic precursor used in the step of forming the organic molecular layer OM further includes a cross-linking functional group, —Z₅X_{c}Rₐ₃, on its side, i.e., when x is 1 or more in Chemical Formula 5.

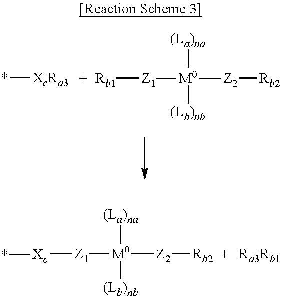

In Reaction Scheme 3, *—X_{c}Rₐ₃ may be a functional group located on the side of the organic monomer within the previously formed organic molecular layer OM, i.e., a cross-linking functional group. The inorganic precursor from Chemical Formula 6, supplied during the inorganic precursor dosing step, can react with this cross-linking functional group and be placed between the organic monomers within the organic molecular layer OM. In this process, Rₐ₃R_{b1} may be generated as a reaction by-product. Afterward, during the purge step, the remaining inorganic precursors and the by-products from Reaction Scheme 2 and Reaction Scheme 3 (Rₐ₂R_{b1} and Rₐ₃R_{b1}) may be purged. In Reaction Scheme 3, each functional group may be the same as those defined in Chemical Formula 5 and Chemical Formula 6.

However, this is not limited thereto. In the case where the organic precursor used in the step of forming the organic molecular layer OM contains an amide group or an amine group within the chain of the alkylene group that forms its body, X_{c} may be N in Reaction Formula 3, and Rₐ₃ may be a hydrogen or a C1 to C2 alkyl group; specifically, —X_{c}Rₐ₃ may be —NH— or —NRₐ₃—.

As an example, in forming the FLx layer in FIG. 2, the organic precursor used is an organic precursor further including a crosslinking functional group, —Z₅X_{c}Rₐ₃, so that reactions of Reaction Schemes 2 and 3 can occur simultaneously in the inorganic precursor dosing step. As a result, the upper organic monomer OX within the FLx layer reacts with the inorganic precursor to bind the main inorganic monomer MX (Reaction Scheme 2), and some of the organic monomers OX may be bound to side inorganic monomers MZ by the reaction of the crosslinking functional group, —Z₅X_{c}Rₐ₃, with the inorganic precursor (Reaction Scheme 3), and the crosslinking functional group, —Z₅X_{c}Rₐ₃, of other parts of the organic monomers OX may remain without reacting with the inorganic precursor. M⁰ in Reaction Scheme 2 is represented as M^{X}, and M⁰ in Reaction Scheme 3 is represented as M^{Z} in FIG. 2. In addition, although the ligands La and Lb are shown not to be bonded to M^{X} in the drawing, this is not limited thereto, and na units of La and nb units of Lb may be bonded to M^{X}. In addition, although Z₁, Z₂, Z₃, Z₄, and Z₅ in the chemical formulas and reaction formulas are shown in FIG. 2 as bonds, this is not limited thereto.

Meanwhile, the organic monomer OY in the FL_{Y} layer may be an organic monomer formed by carrying out Reaction Scheme 1 (x is 0) using an organic precursor that does not include a crosslinking functional group, specifically, an organic precursor in Chemical Formula 5 where x is 0 and does not have a reactive functional group in the body MR. In this case, in forming the inorganic monomolecular layer MY, only the reaction of Reaction Scheme 2 may occur. In the drawing, it is shown that na and nb of Chemical Formula 6 and Reaction Scheme 2 are both 1, but the present invention is not limited thereto.

In addition, although both the FL_{X} layer and the FL_{Y} layer are formed in FIG. 2, this is not limited thereto, and only the FLx layer may be formed. When forming the organic monomer OY, unlike the main inorganic monomer MX in the FLx layer, the side inorganic monomer MZ may not have sufficient spatial space to participate in the reaction with the organic precursor dosed thereafter and may retain the —R_{b2} bond bonded to M^{Z}. This also applies when only the FL_{X} layer is continuously formed.

The control unit 150 may control the opening and closing of the valves and the temperature of the chamber.

In this way, the reaction as in the above Reaction Scheme 1 can be carried out in a pressurized environment of 50 mTorr or more, specifically 100 mTorr or more, of the pressure of the organic precursor alone. In this case, the organic precursor can react densely on the substrate, so that the chains of the organic precursor can be arranged upwardly, for example, in a vertical direction, with respect to the substrate 10. Furthermore, the reaction as in the above Reaction Scheme 1 can be carried out in a state where the gas outlet valve 142 is closed, that is, specifically, in a pressurized stagnant environment rather than a laminar flow environment. In this case, the dense reaction of the organic precursor on the substrate can be carried out more efficiently. However, the present invention is not limited thereto, and the organic precursor can be supplied alone without a carrier gas while the gas outlet valve 142 is open, so that the reaction can be carried out in a state where a laminar flow is formed within the chamber.

A molecular layer deposition device according to one embodiment of the present invention can perform a cycle including a step of forming a main inorganic monomolecular layer (MM of Chemical Formula 1) and a step of forming an organic molecular layer (OM of Chemical Formula 1) multiple times, specifically a number of times represented by l in Chemical Formula 1.

In cases where the first main inorganic monomolecular layer MX or the second main inorganic monomolecular layer MY is formed of multiple main inorganic monomolecular layers (where n in Chemical Formula 1 is 2 or more), a unit cycle comprising the inorganic precursor dosing step and the purge step according to the previously described Reaction Formula 2 (or both Reaction Formula 2 and Reaction Formula 3), a reaction gas dosing step for dosing a reaction gas to react with the inorganic precursor chemically bonded to the lower layer, and a purge step for supplying a purge gas to purge unreacted reaction gas and reaction byproducts can be repeated. In this case, the reaction gas may be a gas containing hydrogen or oxygen (e.g., O₂, O₃, H₂O), a gas containing nitrogen (e.g., NH₃), etc.

FIG. 2 and FIGS. 4 to 7 are schematic diagrams sequentially illustrating a photolithography method according to an embodiment of the present invention.

As described with reference to FIG. 2, a multilayer molecular film photoresist 30 may be formed.

Referring to FIG. 4, a portion of the multilayer molecular film photoresist 30 may be irradiated with radiation hv, specifically, EUV or Ebeam. The EUV may have a wavelength of 13.5 nm. In this case, the metal atoms M^{X}, M^{Y}, or M^{Z} within the main inorganic monomer, for example, the first main inorganic monomer MX and the second main inorganic monomer MY, and the side inorganic monomer MZ, may absorb the radiation and generate secondary electrons.

These secondary electrons may form cross-links between adjacent molecular lines ML. Specifically, the unreacted functional group —R_{b2} of the side inorganic monomer MZ may react with the remaining crosslinking functional group —X_{c}Rₐ₃ of the first organic monomer OX to generate R_{b2}Rₐ₃ as a reaction by-product, while forming an —X_{c}— bond between the metal atom M^{Z} of the side inorganic monomer MZ and the body MR of the first organic monomer OX.

In addition, the first main inorganic monomer MX corresponds to the case where both na and nb in Chemical Formula 2 are 0, in which case M^{X} may bond with Xₐ and/or X_{b} of other adjacent molecular lines, specifically, form a coordination bond CB. The second main inorganic monomer MY corresponds to the case where both na and nb in Chemical Formula 3 are 1, in which case M^{Y}-Lₐ and L_{b}-M^{Y} provided in other adjacent molecular lines may form a M^{Y}-Y-M^{Y} bond. Here, Y may be O, S, Se, N, or P.

These M^{Y}-Y-M^{Y} bonds, bonds between M^{X} and Xₐ and/or X_{b}, and M^{Z}-X_{c}-MR bonds are cross-links formed by exposure, and may not be etched by a developer gas or developing plasma, as an example of a developer that develops a multilayer molecular film photoresist pattern formed by exposure.

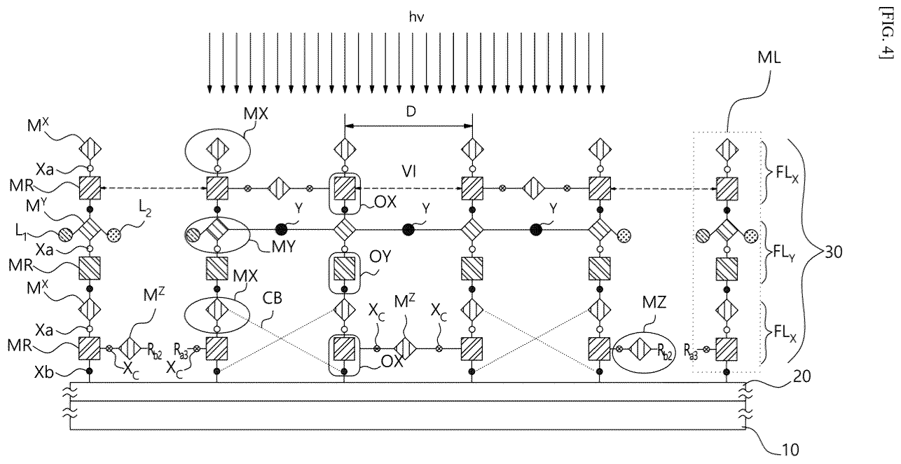

Referring to FIG. 5, a multilayer molecular film photoresist 30 exposed by radiation may be exposed to a developer. In this case, the developer can remove all areas except for the cross-linked portions formed between adjacent molecular lines ML, thereby forming a multilayer molecular film photoresist pattern 31. The developer can be a developing solution, such as water, isopropyl alcohol (IPA), methyl isobutyl ketone (MIBK), or tetramethylammonium hydroxide (TMAH), or a developing gas, such as CF₄, Ar, O₂, or CHF₃, or plasma generated therefrom.

Referring to FIG. 6, the etching target film 20 may be etched using the multilayer molecular film photoresist pattern 31 as a mask. This etching can be, for example, plasma etching.

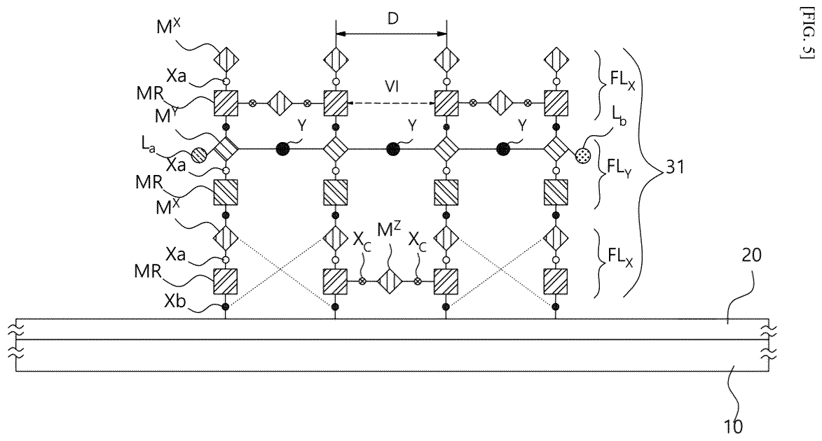

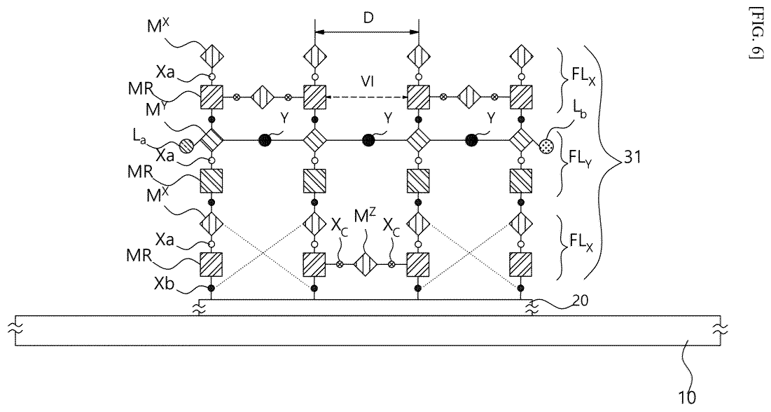

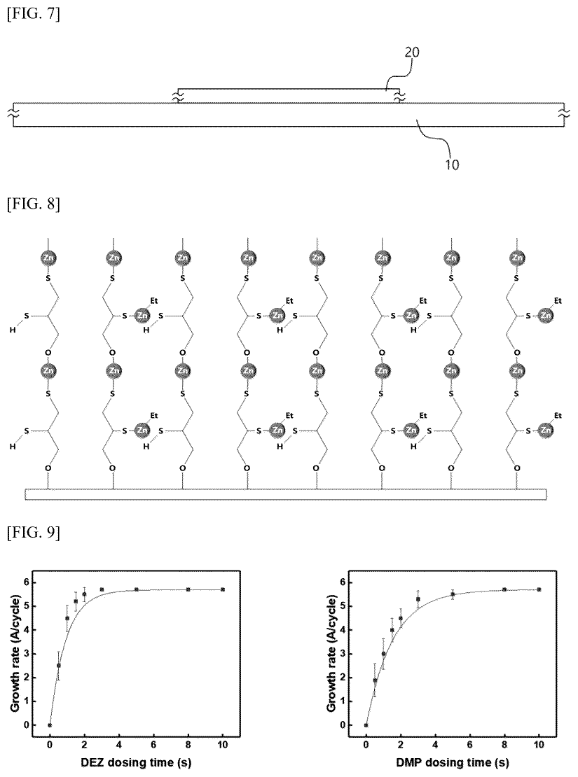

Referring to FIG. 7, the multilayer molecular film photoresist pattern 31 can be removed. This may be done using the ashing method.

As described above, the multilayer molecular film photoresist 30 is formed by self-assembly of inorganic and organic monomers that are connected by bonds within the molecular lines. Therefore, the molecular lines can individually grow upward from the substrate without becoming entangled or tilted, and the molecular lines can be uniformly arranged in the transverse direction. The molecular lines can be formed so densely that van der Waals interactions VI can occur between the organic molecules within the adjacent molecular lines. The van der Waals interactions can stabilize the laterally adjacent molecular lines, thereby preventing the pattern from collapsing even when the aspect ratio is high. The dense formation of the molecular lines may be attributed to the fact that the dosing of the organic precursor and/or the inorganic precursor is performed without using a carrier gas, thereby increasing the pressure of the organic precursor and/or the inorganic precursor within the chamber. To this end, the dosing of the organic precursor and/or the inorganic precursor can be performed with the gas outlet of the chamber closed. In this case, the height of the unit layer can be approximately equal to the length of the unit layer, which reflects the actual sizes of the atoms within the unit layer and the actual lengths of the bonds between the atoms.

In this way, the spacing between the molecular lines (D in FIG. 1 or 2) may be very small, less than 1 nm, specifically less than 0.5 nm. In addition, by separating the molecular lines rather than the particles during exposure and development, the line edge roughness (LER), which refers to the edge roughness of the pattern, may be significantly reduced. For example, a very low line edge roughness of less than 1.2 nm may be achieved. The resolution may also be significantly reduced. For example, a resolution of less than 6 nm may be achieved. In addition, the multilayer molecular film photoresist 30 includes a light-absorbing inorganic monomer having an inorganic atom with a very high light absorption coefficient for EUV, specifically a metal atom having a 4d or 5d orbital, so that it can exhibit a low stochastic failure and high photosensitivity (e.g., 10 mJ/cm²) even for EUV with a low photon density.

In addition, when the body (MR in Chemical Formula 5) as an organic precursor or organic monomer is a linear chain or a non-aromatic ring, molecular lines can be formed more densely by van der Waals bonding between organic monomers within adjacent molecular lines. In addition, when a crosslinking functional group, —Z₅X_{c}Rₐ₃, is directly or indirectly bonded to a carbon atom other than the alpha carbon adjacent to Z₃ and Z₅ among the carbons constituting the body MR in Chemical Formula 5 and arranged between the molecular lines, the gap between the organic monomers can be controlled so as not to be too narrow. Accordingly, in the inorganic precursor dosing step, the inorganic precursor can be introduced to and react with the crosslinking functional group, —Z₅X_{c}Rₐ₃, located between the molecular lines, and as a result, the inorganic monomers can be arranged between the molecular lines and bonded to molecular lines. Meanwhile, the side inorganic monomer may not react with the organic precursor in the subsequent organic precursor dosing step due to insufficient space for introducing the organic precursor, and may retain an unreacted functional group Rₐ₃ at the terminal. The terminal unreacted functional group Rₐ₃ of the side inorganic monomer additionally reacts with the organic monomer upon irradiation and is crosslinked, thereby forming a photoresist pattern with excellent etching resistance.

Hereinafter, a preferred experimental example is presented to help understanding of the present invention. However, the following experimental examples are only to aid the understanding of the present invention, and the present invention is not limited by the following experimental examples.

### Manufacturing Example 1: Photoresist Manufacturing Example 1

FIG. 8 illustrates a multilayer molecular film photoresist having a vertical molecular line structure formed according to this manufacturing example.

Referring to FIG. 8, a substrate was loaded into a chamber equipped with a gas inlet and a gas outlet, and the substrate temperature was heated to 100° C. With the gas outlet closed, DMP (2,3-dimercapto propanol), an organic precursor, was supplied onto the substrate through the gas inlet without a carrier gas until the chamber pressure reached 200 mTorr (organic precursor supply step). Then, the chamber inlet was also closed, maintaining the chamber pressure at 200 mTorr, and the organic precursor was reacted on the substrate for 1 second (organic precursor exposure step). Subsequently, with both the gas inlet and gas outlet open, argon as a purge gas was supplied through the gas inlet for 600 seconds to purge reaction byproducts and residual reaction gases (organic precursor purge step). The organic precursor supply step, the organic precursor exposure step, and the organic precursor purge step constitute an organic precursor sub-cycle.

Thereafter, with the gas outlet closed, DEZ (diethyl zinc), a Zn precursor, was supplied as an inorganic precursor onto the organic precursor layer through the gas inlet without a carrier gas until the chamber pressure reached 1 Torr (inorganic precursor supply step). Thereafter, the gas inlet was also closed, and the chamber pressure was maintained at 1 Torr, while the Zn precursor was reacted on the surface of the organic precursor layer for 1 second (inorganic precursor exposure step). Thereafter, with both the gas inlet and gas outlet open, argon, a purge gas, was supplied through the gas inlet for 200 seconds to purge reaction by-products and residual reaction gases (inorganic precursor purge step). The inorganic precursor supply step, the inorganic precursor exposure step, and the inorganic precursor purge step constitute an inorganic precursor sub-cycle.

A unit cycle consisting of one inorganic precursor sub-cycle and one organic precursor sub-cycle was performed 33 times to form a multilayer molecular film photoresist having a thickness of approximately 20 nm.

### Manufacturing Example 2: Photoresist Manufacturing Example 2

The same organic precursor sub-cycle as Manufacturing Example 1 was performed. Then, with the gas outlet closed, an inorganic precursor, a Hf precursor (TDMA)Hf (tetrakisdimethylamido hafnium), was supplied without a carrier gas through the gas inlet onto the organic precursor layer until the chamber pressure reached 750 mTorr (inorganic precursor supply step). The gas inlet was then closed, and the chamber pressure was maintained at 750 mTorr, allowing the Hf precursor to react on the surface of the organic precursor layer for 1 second (inorganic precursor exposure step). Then, with both the gas inlet and gas outlet open, argon as a purge gas was supplied through the gas inlet for 300 seconds to purge reaction by-products and residual reaction gases (inorganic precursor purge step). The inorganic precursor supply step, the inorganic precursor exposure step, and the inorganic precursor purge step constitute the inorganic precursor sub-cycle.

A unit cycle consisting of one inorganic precursor subcycle and one organic precursor subcycle was performed 31 times to form a multilayer molecular film photoresist with a thickness of approximately 20 nm.

### Manufacturing Example 3: Photoresist Manufacturing Example 3

The same organic precursor sub-cycle as in Manufacturing Example 1 was performed. Then, with the gas outlet closed, the inorganic precursor, a Ti precursor (TDMA)Ti (tetrakisdimethylamido titanium), was supplied onto the organic precursor layer through the gas inlet without a carrier gas until the chamber pressure reached 1 Torr (inorganic precursor supply step). Then, with the gas inlet also closed and the chamber pressure maintained at 1 Torr, the Ti precursor was allowed to react on the surface of the organic precursor layer for 1 second (inorganic precursor exposure step). Afterwards, with both the gas inlet and outlet ports open, argon, a purge gas, was supplied through the gas inlet for 300 seconds to purge reaction by-products and residual reaction gases (inorganic precursor purge step). The inorganic precursor supply step, the inorganic precursor exposure step, and the inorganic precursor purge step constitute an inorganic precursor sub-cycle.

A unit cycle consisting of one inorganic precursor sub-cycle and one organic precursor sub-cycle was performed 42 times to form a multilayer molecular film photoresist with a thickness of approximately 20 nm.

FIG. 9 shows graphs showing the film growth rate according to the supply time of each precursor when manufacturing a photoresist according to Manufacturing Example 1. The left graph shows the change in film growth rate as the DEZ supply time was varied while the DMP supply time was fixed at 5 seconds. The right graph shows the change in film growth rate as the DMP supply time was varied while the DEZ supply time was fixed at 2 seconds.

Referring to FIG. 9, the film growth rate saturates after approximately 2 seconds of DEZ supply time and after approximately 5 seconds of DMP supply time. Furthermore, a film growth rate of approximately 6 Å/cycle was achieved by setting the DEZ supply time to 2 seconds and the DMP supply time to 5 seconds.

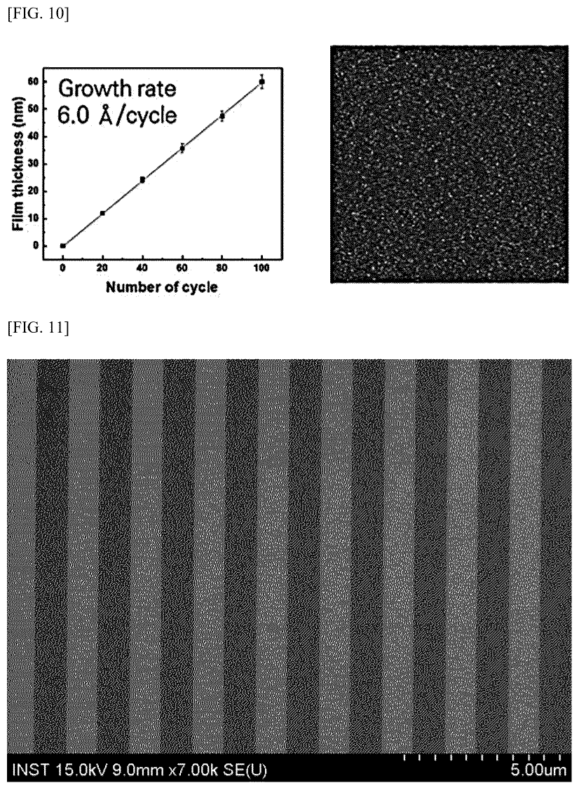

FIG. 10 shows a graph showing the change in film thickness according to the number of cycles of the photoresist according to Manufacturing Example 1, along with an AFM image of the surface.

Referring to FIG. 10, the photoresist according to Manufacturing Example 1 exhibited a film formation rate of 6 Å/cycle and implemented a surface with a small surface roughness.

FIG. 11 shows an SEM image taken after patterning the photoresist obtained in Manufacturing Example 1. Specifically, the photoresist obtained in Manufacturing Example 1 was exposed to e-beam under conditions of 100 kV, 500 pA, and 1500 μC/cm². The photoresist was then developed by being immersed in 2 wt % TMAH (Tetramethylammonium hydroxide) in H₂O for 2 minutes and then immersed in H₂O for 10 seconds.

Referring to FIG. 11, a pattern with a half-pitch line width of 1 μm was clearly formed. The pattern was formed in the exposed portion, and the photoresist according to this example may be defined as a negative photoresist.

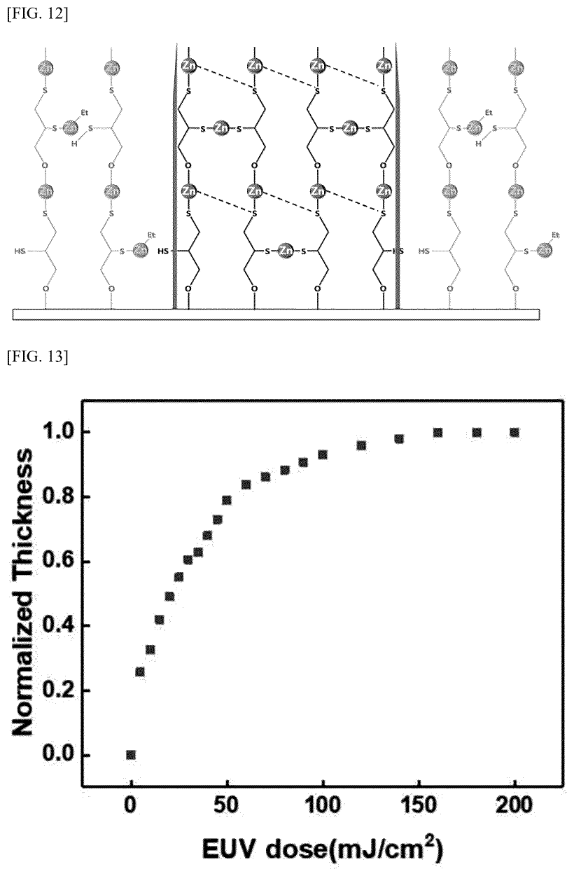

FIG. 12 is a schematic diagram illustrating crosslinking within the photoresist during the exposure process of FIG. 11.

Referring to FIG. 12, it can be assumed that, within the irradiated area, the unreacted functional group of the side inorganic monomers bound to the organic monomers, i.e., the ethyl group, reacts with the unreacted functional group of the adjacent organic monomer, i.e., the thiol group, forming a Zn—S—C bond. Furthermore, the Zn within the inorganic monomers is believed to coordinate with O and/or S within the adjacent organic monomer layer.

It is assumed that these Zn—S—C bonds and coordination bonds cause the exposed area to remain undeveloped, forming a pattern.

FIG. 13 is a graph showing the electron beam sensitivity of the photoresist obtained in Manufacturing Example 1. Specifically, the photoresist obtained in the Manufacturing Example was exposed to EUV at doses ranging from 5 to 200 mJ/cm², then immersed in 2 wt % TMAH (Tetramethylammonium hydroxide) in H₂O for 2 minutes and then immersed in H₂O for 10 seconds for development.

Referring to FIG. 13, the normalized thickness of the negative photoresist in this experiment was indicated as 1 when the thickness right after deposition is maintained after development. The multilayer molecular film photoresist according to the Manufacturing Example exhibited a normalized thickness of 1 at approximately 150 mJ/cm², demonstrating excellent sensitivity.

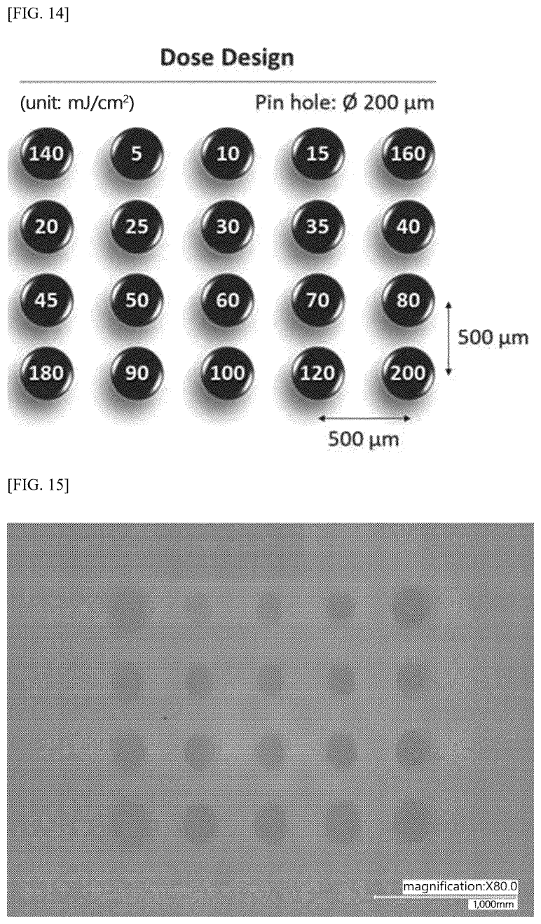

FIG. 14 is a schematic diagram illustrating the EUV irradiation pattern and dose conditions, and FIG. 15 is an optical photograph of the photoresist patterns obtained after irradiating the photoresist according to Manufacturing Example 1 with the EUV pattern illustrated in FIG. 14. Specifically, the photoresist according to Manufacturing Example was exposed to EUV patterns as shown in FIG. 14, then immersed in 2 wt % TMAH (Tetramethylammonium hydroxide) in H₂O for 2 minutes and then immersed in H2O for 10 seconds for development.

Referring to FIGS. 14 and 15, the photoresist according to Manufacturing Example exhibited a thickness of approximately 20 nm immediately after deposition, and when exposed using EUV at a dose of approximately 15 mJ/cm² or higher and developed, exhibited a thickness of approximately 10 nm or higher. This indicates that the EUV sensitivity of the photoresist according to Manufacturing Example 1 was 15 mJ/cm².

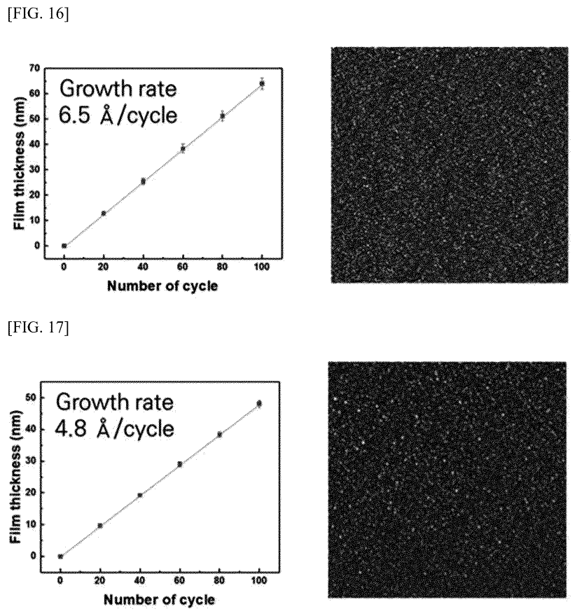

FIG. 16 is a graph showing the change in film thickness according to the number of cycles for the photoresist according to Manufacturing Example 2, along with an AFM image of the surface.

Referring to FIG. 16, the photoresist according to Manufacturing Example 2 exhibited a film growth rate of 6.5 Å/cycle and produced a surface with moderate surface roughness.

FIG. 17 is a graph showing the change in film thickness according to the number of cycles for the photoresist according to Manufacturing Example 3, along with an AFM image of the surface.

Referring to FIG. 17, the photoresist according to Manufacturing Example 3 exhibited a film growth rate of 4.8 Å/cycle and produced a surface with moderate surface roughness.

While the exemplary embodiments of the present invention have been described above, those of ordinary skill in the art should understood that various changes, substitutions and alterations may be made herein without departing from the spirit and scope of the present invention as defined by the following claims.

1. A multilayer molecular film photoresist comprising:
a plurality of molecular lines extending upward from a substrate and arranged laterally, each molecular line comprising linearly connected monomers represented by the following Chemical Formula 1: 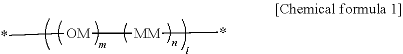
in the Chemical formula 1, one of the *s is a bond to a functional group in a lower monomer, and the other is a bond to a functional group in an upper monomer, OM is an organic monomer, MM is a main inorganic monomer comprising a metal atom, m is 1 to 2, n is 1 to 2, and l is 1 to 1000;
a side inorganic monomer positioned between the molecular lines, bonded to a side of the organic monomer (OM) in one of the molecular lines, and comprising a metal atom; and
a crosslinking functional group bonded to a side of the organic monomer (OM) in another of the molecular lines.

2. The multilayer molecular film photoresist according to claim 1, wherein van der Waals interactions exist between the organic monomers within the laterally adjacent molecular lines.

3. The multilayer molecular film photoresist according to claim 1, wherein the main inorganic monomer is represented by the following Chemical Formula 2: 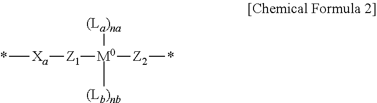
in the Chemical Formula 2, one of the *s is a bond with a functional group in a lower monomer, and the other is a bond with a functional group in an upper monomer,
Xₐ is O, S, Se, NR (R is H or CH₃), or PR (R is H or CH₃),
M⁰ is the metal atom and M⁰ is Sn, Sb, Te, Bi, Zr, Al, Hf, Zn, In, Al, Ti, Cu, W, or Si,
Z₁ and Z₂ are, regardless of each other, a direct bond, a substituted or unsubstituted linear or branched alkylene group having 1 to 20 carbon atoms, a substituted or unsubstituted linear or branched alkylene oxide having 1 to 20 carbon atoms, a substituted or unsubstituted linear or branched alkyleneamino having 1 to 20 carbon atoms, a substituted or unsubstituted linear or branched alkylenesilylamino having 1 to 20 carbon atoms, a substituted or unsubstituted linear or branched alkylenethio having 1 to 20 carbon atoms, a substituted or an unsubstituted linear or branched alkyleneseleno having 1 to 20 carbon atoms, or a substituted or unsubstituted linear or branched alkylenephosphino having 1 to 20 carbon atoms, and
Lₐ and L_{b}, regardless of each other, are a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, a C1 to C5 alkylphosphino group, acetate, or aryloxy, and
a sum of na and nb is an integer from 0 to 4.

4. The multilayer molecular film photoresist according to claim 3, wherein both na and nb are 0.

5. The multilayer molecular film photoresist according to claim 1, wherein the side inorganic monomer is represented by the following Chemical Formula 3: 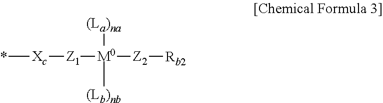
in the Chemical Formula 3, * is a bond with the organic monomer,
X_{c} is O, S, Se, NR (R is H or CH₃), or PR (R is H or CH₃),
M⁰ is the metal atom and M⁰ is Sn, Sb, Te, Bi, Zr, Al, Hf, Zn, In, Al, Ti, Cu, W, or Si,
Z₁ and Z₂ are, regardless of each other, a direct bond, a substituted or unsubstituted linear or branched alkylene group having 1 to 20 carbon atoms, a substituted or unsubstituted linear or branched alkylene oxide having 1 to 20 carbon atoms, a substituted or unsubstituted linear or branched alkyleneamino having 1 to 20 carbon atoms, a substituted or unsubstituted linear or branched alkylenesilylamino having 1 to 20 carbon atoms, a substituted or unsubstituted linear or branched alkylenethio having 1 to 20 carbon atoms, a substituted or an unsubstituted linear or branched alkyleneseleno having 1 to 20 carbon atoms, or a substituted or unsubstituted linear or branched alkylenephosphino having 1 to 20 carbon atoms, and
Lₐ and L_{b}, regardless of each other, are a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, a C1 to C5 alkylphosphino group, acetate, or aryloxy,
the sum of na and nb is an integer from 0 to 4, and
R_{b2} is a halogen group, a C1 to C5 alkyl group, a C1 to C5 alkylsilylamino group, a C1 to C5 alkoxy, a C1 to C5 alkylthio group, a C1 to C5 alkylseleno group, a C1 to C5 alkylamino group, or a C1 to C5 alkylphosphino group.

6. The multilayer molecular film photoresist according to claim 5, wherein both na and nb are 0.

7. The multilayer molecular film photoresist according to claim 1,
wherein the crosslinking functional group is *—Z₅X_{c}Rₐ₃,
wherein * is a bond with the organic monomer, Z₅ is a direct bond or a substituted or unsubstituted, linear or branched alkylene group having C1 to C5, X_{c} is O, S, Se, NR (R is H or CH₃), or PR (R is H or CH₃), and Rₐ₃ is hydrogen or a C1 to C2 alkyl group.

8. The multilayer molecular film photoresist according to claim 1,
wherein the organic monomer is represented by the following Chemical Formula 4: 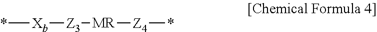
in the Chemical Formula 4, one of the *s is a bond with a functional group in a lower monomer, and the other is a bond with a functional group in an upper monomer;
X_{b} is O, S, Se, NR (R is H or CH₃), or PR (R is H or CH3);
Z₃ and Z₄ are, regardless of each other, direct bonds or linear or branched alkylene groups having C1 to C5;
MR is a body having a linear chain having 2 to 7 carbons or a non-aromatic or aromatic ring having 3 to 18 carbons; and
the side inorganic monomer or the crosslinking functional group is bonded to the body (MR).

9. The multilayer molecular film photoresist according to claim 8, wherein the MR is a linear alkylene group having C2 to C6.

10. A multilayer molecular film photoresist comprising:
a plurality of molecular lines extending upwardly from a substrate and arranged laterally, each molecular line comprising linearly connected monomers, wherein the monomers comprise a plurality of main inorganic monomers including metal atoms and organic monomers connected between at least some of the main inorganic monomers, and
side inorganic monomers positioned between the molecular lines, bonded to sides of the organic monomers, and comprising metal atoms.

11. The multilayer molecular film photoresist according to claim 10, wherein the main inorganic monomers and organic monomers located within the molecular lines are connected by one bond selected from the group consisting of —O—, —S—, —Se—, —NR— (R is H or CH₃) and —PR— (R is H or CH₃) contained in any one of these monomers.

12. The multilayer molecular film photoresist according to claim 10, wherein the organic monomers and the side inorganic monomers are connected by one bond selected from the group consisting of —O—, —S—, —Se—, —NR— (R is H or CH₃) and —PR— (R is H or CH₃) contained in any one of these monomers.

13. The multilayer molecular film photoresist according to claim 10, wherein the metal atom contained in the main inorganic monomer or the side inorganic monomer is Sn, Sb, Te, Bi, Zr, Al, Hf, Zn, In, Ti, Cu, W, or Si.

14. The multilayer molecular film photoresist according to claim 10, wherein van der Waals interactions exist between the organic monomers within the laterally adjacent molecular lines among the molecular lines.

15. The multilayer molecular film photoresist according to claim 10, wherein each of the molecular lines is formed by alternating stacking of the main inorganic monomers and the organic monomers.

16. The multilayer molecular film photoresist according to claim 10, wherein the multilayer molecular film photoresist is a photoresist for EUV.

17. A method for manufacturing a photoresist pattern, comprising:
providing a multilayer molecular film photoresist comprising a plurality of molecular lines extending upward from a substrate and arranged laterally, each molecular line comprising linearly connected monomers represented by the following Chemical Formula 1: 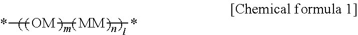
in Chemical formula 1, one of the *s is a bond to a functional group in a lower monomer, and the other is a bond to a functional group in an upper monomer; OM is an organic monomer; MM is a main inorganic monomer comprising a metal atom; m is 1 to 2, n is 1 to 2, and l is 1 to 1000,
a side inorganic monomer positioned between the molecular lines, bonded to a side of the organic monomer (OM) in one of the molecular lines, and comprising a metal atom; and a crosslinking functional group bonded to a side of the organic monomer (OM) in another of the molecular lines;
irradiating a portion of the multilayer molecular film photoresist with Ebeam or EUV radiation to crosslink the side inorganic single molecules with the crosslinkable functional group; and
developing and removing the portion of the multilayer molecular film photoresist not exposed to the radiation.

18. A method for manufacturing a photoresist pattern, comprising:
loading a substrate into a chamber;
performing an organic precursor sub-cycle, which includes supplying an organic precursor of the following Chemical Formula 5 into the chamber, reacting the organic precursor on the substrate, and then purging any remaining reaction gas within the chamber;
performing an inorganic precursor sub-cycle, which includes supplying an inorganic precursor of the following Chemical Formula 6 into the chamber, reacting the inorganic precursor on the organic precursor, and then purging any remaining reaction gas within the chamber;
performing multiple unit cycles including the organic precursor sub-cycle and the inorganic precursor sub-cycle to form a multilayer molecular film photoresist;
irradiating a portion of the multilayer molecular film photoresist with Ebeam or EUV radiation; and
developing an area of the multilayer molecular film photoresist not exposed to the radiation: 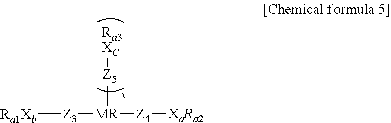
in the Chemical Formula 5, Rₐ₁, Rₐ₂, and Rₐ₃ are hydrogen or C1 to C2 alkyl groups regardless of each other, Xₐ, X_{b}, and X_{c} are O, S, Se, NR (R is H or CH₃) or PR (R is H or CH₃) regardless of each other, Z₃, Z₄, and Z₅ are direct bonds or substituted or unsubstituted and linear or branched alkylene groups of C1 to C3 regardless of each other, MR is a body having a linear chain having 2 to 7 carbons or a non-aromatic or aromatic ring having 3 to 18 carbons, x is 1 or 2, 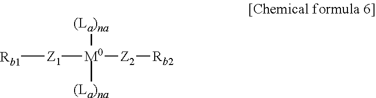
in the Chemical Formula 6, R_{b1} and R_{b2}, regardless of each other, are a halogen group, a C1 to C5 alkyl group, a C1 to C5 alkylsilylamino group, a C1 to C5 alkoxy, a C1 to C5 alkylthio group, a C1 to C5 alkylseleno group, a C1 to C5 alkylamino group, or a C1 to C5 alkylphosphino group,
M⁰ is Sn, Sb, Te, Bi, Zr, Al, Hf, Zn, In, Al, Ti, Cu, W, or Si,
Z₁ and Z₂ are, regardless of each other, a direct bond, a substituted or unsubstituted linear or branched alkylene group having 1 to 20 carbon atoms, a substituted or unsubstituted linear or branched alkylene oxide having 1 to 20 carbon atoms, a substituted or unsubstituted linear or branched alkyleneamino having 1 to 20 carbon atoms, a substituted or unsubstituted linear or branched alkylenesilylamino having 1 to 20 carbon atoms, a substituted or unsubstituted linear or branched alkylenethio having 1 to 20 carbon atoms, a substituted or an unsubstituted linear or branched alkyleneseleno having 1 to 20 carbon atoms, or a substituted or unsubstituted linear or branched alkylenephosphino having 1 to 20 carbon atoms, and
Lₐ and L_{b}, regardless of each other, are a halogen group, a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, a C1 to C5 alkylphosphino group, acetate, or aryloxy, and
a sum of na and nb is an integer from 0 to 4.
